(19) United States
(12) Patent Application Publication
(10) Pub. No.: US 2026/0346783 A1
(43) Pub. Date: Nov. 5, 2026

(54) SYSTEM AND METHOD FOR GENERATING TRAILER LIGHTING CONTROL SIGNALS BASED ON MEASURED VEHICLE LIGHTING CURRENT

(71) Applicant: B & W Custom Truck Beds, Inc., Humboldt, KS (US)

(72) Inventors: Chandler Flinders, College Station, TX (US); Michael Hall, Provo, UT (US)

(73) Assignee: B & W Custom Truck Beds, Inc., Humboldt, KS (US)

(21) Appl. No.: 19/662,560

(22) Filed: Apr. 29, 2026

Related U.S. Application Data
(60) Provisional application No. 63/797,695, filed on Apr. 30, 2025.

(51) Int. Cl. B60Q 1/34; B60Q 1/44; B60Q 11/00; G01R 19/00; G01R 19/25; G01R 19/252; G01R 31/00

(52) U.S. Cl. CPC B60Q 1/346; B60Q 1/44; B60Q 11/007; G01R 19/0092; G01R 19/2506; G01R 19/2513; G01R 19/252; G01R 31/007

(57) ABSTRACT

A system and method for generating trailer lighting control signals based on measured current in one or more vehicle lighting conductors are disclosed. A current sensor electrically coupled to a vehicle lighting conductor produces a measured current signal representative of electrical behavior associated with vehicle lighting functions. The measured current signal is conditioned and digitized, and logic and control circuitry analyzes timing characteristics of the digitized signal to determine vehicle lighting activation states, including sustained and periodic activation states. Based on the determined activation state, the logic and control circuitry generates one or more trailer lighting control signals. A trailer lighting control module receives the generated control signals and actively drives corresponding trailer lighting outputs. The system allows reliable trailer lighting control in vehicles employing electronically controlled lighting architectures, including LED-based systems and systems utilizing modulation or shared conductors.

### CROSS REFERENCE TO RELATED APPLICATIONS

This application claims the benefit of U.S. Provisional Patent Application Serial No. 63/797,695, filed on Apr. 30, 2025 which is hereby incorporated by reference in its entirety.

### FIELD OF THE INVENTION

The present invention relates generally to vehicle/trailer lighting interfaces and control systems and, more particularly, to systems and methods for determining vehicle lighting states from electrical current measurements and generating corresponding trailer lighting control signals.

### BACKGROUND

Vehicles designed for towing trailers typically include electrical connectors and wiring outputs that allow a trailer wiring harness to be coupled to the vehicle’s lighting system so that corresponding lights on the trailer - such as turn signals, brake lights, and running lights - are activated in coordination with the vehicle lights. In conventional systems still in use on many older vehicles, trailer lighting circuits are simply connected in parallel with the vehicle lighting circuits using standardized wiring harnesses and connectors. This arrangement allows the trailer lights to illuminate simultaneously with the corresponding vehicle lights, thus maintaining synchronization between lights that are illuminated on the vehicle and corresponding lights on an attached trailer.

Traditionally, most vehicle lighting systems used incandescent bulbs that draw relatively high, and relatively steady, current levels when activated. In such straightforward systems, direct parallel wiring or simple voltage-based detection methods were generally sufficient to drive and activate trailer lighting circuits reliably.

Modern vehicles, however, increasingly use light-emitting diode (LED) lighting systems and electronically controlled lighting modules. These systems often use pulse-width modulation (PWM), multiplexed signal architectures, and shared conductor arrangements to regulate brightness, reduce power consumption, and integrate multiple lighting functions within a single lighting module. In many vehicle architectures, multiple lighting functions, such as brake lights, turn signals, and running lights, are supplied through common conductors and/or controlled by internal vehicle lighting modules that generate complex current waveforms rather than simple steady-state voltage signals.

As a result, the electrical characteristics present on modern vehicle lighting conductors may include low-magnitude current levels, high-frequency modulation signals, transient events, and non-zero baseline currents. Thus, a measured current on any given conductor may represent the combined behavior of multiple lighting functions and may vary dynamically depending on vehicle operating conditions. These characteristics make it difficult to determine, based solely on raw voltage or current levels, which specific lighting function is active at a given time.

In view of these changes to modern vehicle electrical systems, conventional trailer wiring approaches that use direct parallel connections may not function reliably with modern vehicle lighting systems. In fact, directly connecting older, conventional parallel-wired trailer lighting modules may interfere with modern vehicle lighting control modules, may trigger fault detection systems, may fail to properly interpret multiplexed or modulated signals, and may fail to properly light a corresponding trailer light when required. Similarly, simple threshold-based current and voltage detection methods may not be adequate for distinguishing between different lighting functions when multiple functions share a conductor or with modulates signals.

Furthermore, in some vehicle architectures, the activation of certain lighting functions may not correspond to a simple on/off electrical condition on a dedicated wire. Instead, the signal on the lighting wire may comprise complex waveform patterns that must be interpreted over time to determine whether, for example, a turn signal, brake light, running light, or other function is active.

Existing trailer lighting interface systems that rely on conventional current sensing arrangements, including contactless sensing approaches developed primarily for higher-current or less complex vehicle lighting circuits, are generally unable to reliably detect very low magnitude current signals or higher-frequency current variations present in modern LED-based and multiplexed vehicle lighting architectures. As a result, such systems may fail to correctly identify lighting activation states or may produce erroneous trailer lighting outputs when used with such vehicle systems.

Thus, it can be seen that there remains a need in the art for improved systems and methods capable of interfacing with modern vehicle lighting systems and reliably controlling trailer lighting in response to detected vehicle lighting activity without adversely affecting the vehicle’s modern electrical architecture.

### SUMMARY OF THE INVENTION

Embodiments of the present invention are directed to systems and methods for generating trailer lighting control signals based on measured current in one or more vehicle lighting conductors. The system is configured to detect activation states of vehicle lighting functions from electrical current measurements and to generate corresponding control signals and/or waveforms for activating and controlling lighting elements of an attached trailer.

In one embodiment, the system includes at least one current sensor electrically coupled to a vehicle lighting conductor that supplies power to one or more vehicle lighting elements. The current sensor is configured to measure current flowing through the vehicle lighting conductor and to produce a measured current signal representative of the electrical behavior of the flowing current. The current sensor may be implemented as an inline sensor electrically connected in series with the vehicle lighting conductor, or in some embodiments may be another suitable current measurement device.

In some embodiments, the measured current signal is provided to signal conditioning circuitry and to an analog-to-digital converter (ADC), which produces a digitized representation of the current signal. The digitized current signal is communicated to logic and control circuitry configured to execute instructions for determining one or more vehicle lighting activation states from the measured current.

In a preferred embodiment, the logic and control circuitry analyzes timing characteristics of the digitized current signal to distinguish between different lighting functions that may be present on the vehicle lighting conductor. Such timing characteristics may include sustained current levels, transient current transitions, periodic current variations, and combinations thereof. By evaluating changes in the magnitude, duration, and repetition of current variations over time, the logic and control circuitry determines whether a corresponding vehicle lighting function, such as a turn signal, brake light, running light, or hazard light, is active.

In some embodiments, the system is specifically configured to detect and analyze low magnitude and/or high-frequency current signals characteristic of modern electronically controlled vehicle lighting systems, including LED-based and multiplexed lighting architectures. By combining high-sensitivity current measurement with signal analysis over time, the system is capable of distinguishing between overlapping or multiplexed lighting functions present on a single conductor. This combination of enhanced sensing capability and signal interpretation allows reliable detection and classification of vehicle lighting activation states from electrical signals that are below detection thresholds or otherwise unresolved by conventional trailer lighting interface systems.

In some embodiments, the logic and control circuitry dynamically determines a baseline current level and evaluates relative changes in the digitized current signal with respect to the baseline rather than relying on fixed, absolute thresholds, which allows reliable detection of lighting activation states even in the presence of noise, non-zero baseline currents, drift, or other variations.

In one embodiment, periodic current variations occurring within a predefined frequency range may be identified as corresponding to a turn signal activation state, while sustained increases in current exceeding a threshold duration may be identified as corresponding to a brake activation state or other steady-state light activation. The logic and control circuitry may further distinguish combined activation states by evaluating overlapping temporal characteristics of the measured current signal.

Upon determination of a vehicle lighting activation state, the logic and control circuitry generates a trailer lighting control signal corresponding to the determined state. The trailer lighting control signal may comprise a synthesized control waveform, including a square-wave or other periodic control signal, that is supplied to a trailer lighting control module. The trailer lighting control module preferably includes driver circuitry configured to activate one or more trailer lighting elements in response to the generated control signal. Thus, in this manner, the trailer lighting elements may be controlled according to the determined vehicle lighting activation state without requiring direct parallel electrical connection between the trailer lighting elements and the vehicle lighting elements.

In some embodiments, the generated trailer lighting control signals are based on the determined vehicle lighting activation states rather than on instantaneous modulation present on the vehicle lighting conductor. In other embodiments, high-frequency modulation components of the measured current signal may be filtered or disregarded, and the logic and control circuitry generates a synthesized control waveform corresponding to the determined activation state for the duration of that state.

In some embodiments, the system may include additional current sensors coupled to additional vehicle lighting conductors to provide supplemental information for determining lighting activation states. The logic and control circuitry may combine information from multiple measured current signals to improve reliability and to distinguish between different lighting functions supplied through shared or multiplexed conductors.

Thus, the systems and methods described herein with respect to exemplary embodiments enable reliable control of trailer lighting in vehicles employing modern electronically controlled lighting architectures, including LED-based systems and systems using pulse-width modulation (PWM), multiplexed conductors, or other non-steady-state electrical signaling, as well as with conventional steady-state current systems used on older vehicles.

### BRIEF DESCRIPTION OF THE DRAWINGS

FIG. 1 is a schematic block diagram of a system for generating trailer lighting control signals based on measured current in a vehicle lighting conductor in accordance with an exemplary embodiment of the present invention.

FIG. 2 is a schematic diagram illustrating a vehicle and trailer wiring context including multiple vehicle lighting conductors and corresponding current sensors in accordance with an exemplary embodiment of the present invention.

FIG. 3 is a schematic diagram illustrating an in-line current sensor electrically coupled in series with a vehicle lighting conductor in accordance with an exemplary embodiment of the present invention.

FIG. 4 is a schematic block diagram of a trailer lighting control module including waveform generation logic and driver circuitry in accordance with an exemplary embodiment of the present invention.

FIG. 5 is a graphical representation of a measured current signal as a function of time illustrating baseline current, sustained current increases, periodic current variations, and transient components in accordance with an exemplary embodiment of the present invention.

FIG. 6 is a graphical representation of a digitized current signal derived from the measured current signal of FIG. 5 in accordance with an exemplary embodiment of the present invention.

FIG. 7 is a graphical representation illustrating a determined lighting activation state and a corresponding generated trailer lighting control waveform in accordance with an exemplary embodiment of the present invention.

FIG. 8 is a flow diagram illustrating a method for determining a vehicle lighting activation state and generating corresponding trailer lighting control signals in accordance with an exemplary embodiment of the present invention.

FIG. 9 is a schematic diagram illustrating an alternative exemplary embodiment of the present invention using a contactless current sensor coupled to a vehicle lighting conductor.

### DETAILED DESCRIPTION

The present invention is directed to systems and methods for generating trailer lighting control signals based on measured current in one or more vehicle lighting conductors. As discussed above, modern vehicle lighting systems frequently employ electronically controlled lighting modules, light-emitting diode (LED) elements, pulse-width modulation (PWM), and multiplexed conductors that may supply multiple lighting functions over a shared electrical path. Under such conditions, the electrical behavior present on any particular vehicle lighting conductor may not correspond to a simple steady-state on/off voltage, but instead may comprise dynamically varying current waveforms that reflect one or more lighting activation states for one or more lighting elements.

In order to reliably control trailer lighting in response to such electrical behavior, the present system measures current in at least one vehicle lighting conductor, processes the measured current to determine one or more vehicle lighting activation states, and generates corresponding trailer lighting control signals. The generated control signals are provided to a trailer lighting control module that actively drives lighting elements of an attached trailer. Thus, trailer lighting may be controlled in response to detected vehicle lighting states without requiring direct parallel electrical connection between trailer lighting elements and vehicle lighting elements.

In some preferred embodiments, the current sensing arrangement is configured to resolve very low magnitude current levels and/or relatively high-frequency current variations that may be present in vehicle lighting conductors associated with LED lighting systems, electronically controlled lighting modules, pulse-width modulation (PWM), and multiplexed vehicle wiring architectures. This sensing capability allows the system to detect electrical behaviors that may be below the detection thresholds or outside the effective response range of conventional trailer lighting interface systems. Such low magnitude current levels may correspond to individual lighting functions within multiplexed or shared conductors, and resolving these signals allows separation of multiple lighting states from a single electrical path.

In preferred embodiments, the system may be implemented using one or more in-line current sensors electrically coupled to vehicle lighting conductors, together with signal conditioning circuitry, analog-to-digital conversion, and logic and control circuitry configured to execute instructions for lighting state determination and control signal generation. In alternative embodiments, other current measurement techniques may be used, as will be described in more detail below.

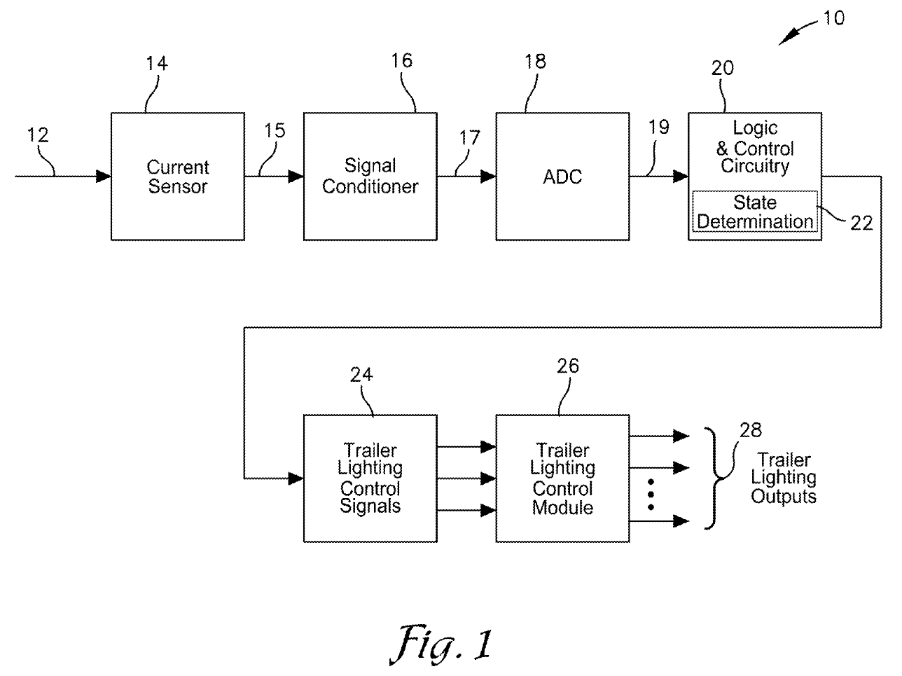

Looking first to FIG. 1, a system for generating trailer lighting control signals in accordance with one exemplary embodiment of the present invention is depicted generally as 10. System 10 includes a vehicle lighting conductor 12 that supplies electrical current to one or more vehicle lighting elements. An in-line current sensor 14 is electrically coupled to the vehicle lighting conductor 12 and is configured to measure current flowing through the conductor. In one embodiment, the current sensor 14 is connected in series with the vehicle lighting conductor 12 such that current supplied to the vehicle lighting elements passes through the current sensor 14.

The current sensor 14 produces a measured current signal 15 that is provided to signal conditioning circuitry 16. The signal conditioning circuitry 16 may include amplification, filtering, and over-voltage and over-current protection components configured to produce a conditioned analog signal suitable for digitization. The conditioned signal 17 is propagated to an analog-to-digital converter (ADC) 18, which generates a digitized current signal 19.

From the signal conditioning circuitry 16, the digitized current signal 19 is communicated to logic and control circuitry 20. The logic and control circuitry 20 preferably includes a microcontroller, processor, programmable logic device, or other computational device operable to execute instructions, and preferably includes associated memory for storing executable instructions and operational parameters. The logic and control circuitry 20 is configured to execute lighting state determination logic 22 that analyzes the digitized current signal to determine one or more vehicle lighting activation states.

Upon determining a vehicle lighting activation state, the logic and control circuitry 20 generates one or more trailer lighting control signals 24, with the trailer lighting control signals 24 further supplied to a trailer lighting control module 26. The trailer lighting control module 26 includes driver circuitry configured to activate one or more trailer lighting outputs 28, which may be connected to a trailer connector for supplying power to corresponding lighting elements of an attached trailer.

In this manner, the system 10 measures current in the vehicle lighting conductor 12, determines the associated vehicle lighting activation state using the logic and control circuitry 20, and generates corresponding trailer lighting control signals to drive corresponding trailer lighting elements.

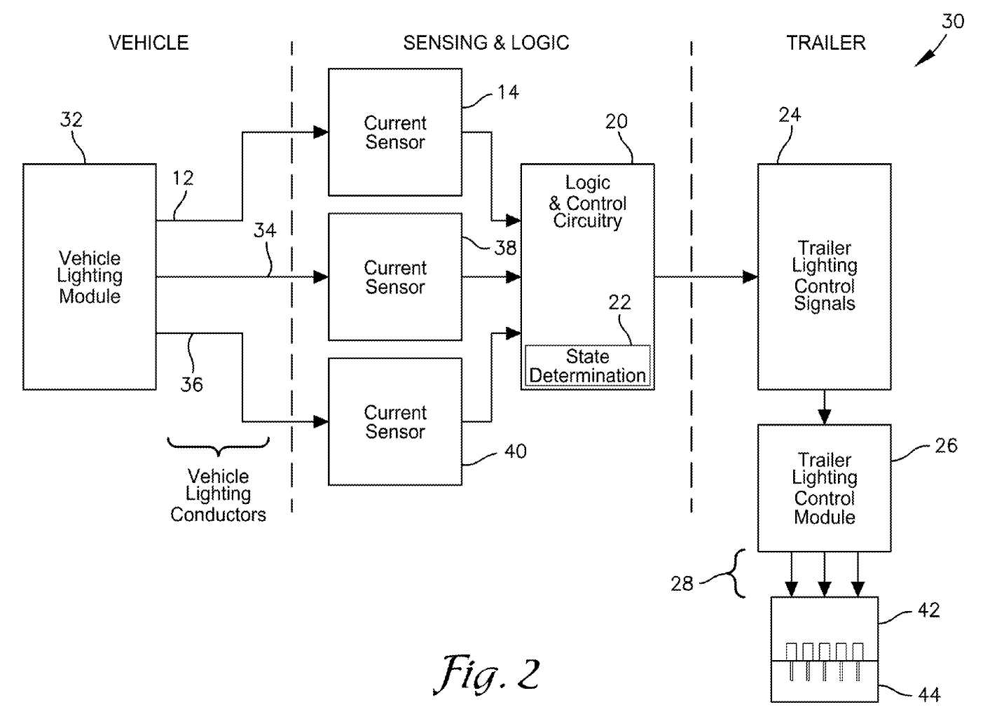

Turning to FIG. 2, a vehicle and trailer wiring configuration in accordance with an exemplary embodiment of the present invention is depicted generally as 30. In this embodiment, a vehicle lighting module 32 supplies current to a vehicle lighting conductor 12, which may represent, for example, a shared conductor supplying multiple lighting functions within a vehicle lighting assembly.

An in-line current sensor 14 is electrically coupled to the vehicle lighting conductor 12 as described above, with the current on the conductor passing through the current sensor, allowing the current to be measured. In some embodiments, additional current sensors may be electrically coupled to additional vehicle lighting conductors. For example, a second vehicle lighting conductor 34 may supply a brake indicator or center high-mounted stop lamp (CHMSL), and a third vehicle lighting conductor 36 may supply a running light or license plate illumination indicator. Corresponding additional current sensors 38 and 40 may be coupled to the conductors 34 and 36, respectively.

The outputs of the current sensors 14, 38, and 40 are supplied to the logic and control circuitry 20, which may combine information from multiple measured current signals to improve reliability in determining lighting activation states. For example, information from a brake indicator conductor may be used to corroborate detection of a brake activation state derived from a shared vehicle lighting conductor.

The logic and control circuitry 20 generates trailer lighting control signals 24, which are supplied to the trailer lighting control module 26. The trailer lighting control module 26 drives trailer lighting outputs 28 connected to a trailer connector 42 for supplying electrical power to lighting elements of an attached trailer 44.

While FIG. 2 illustrates multiple sensed conductors, it should be understood that the system depicted may operate with a single sensed vehicle lighting conductor or with any number of sensed conductors depending on the vehicle architecture and desired level of state discrimination.

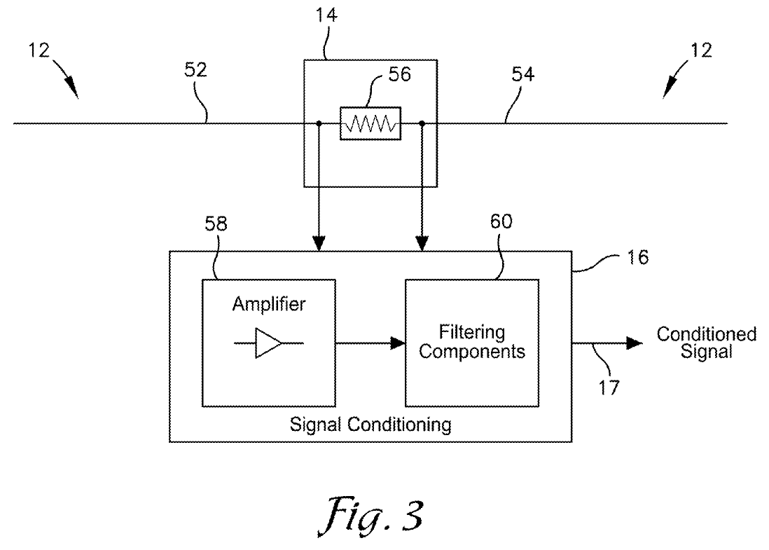

Turning now to FIG. 3, an exemplary embodiment of an in-line current sensor as discussed above with respect to FIGS. 1 and 2 is depicted. In this embodiment, the vehicle lighting conductor 12 includes a first conductor portion 52 and a second conductor portion 54. The in-line current sensor 14 is electrically coupled between the conductor portions 52 and 54 such that electrical current supplied to the vehicle lighting elements passes through the current sensor 14. In one exemplary implementation, the conductor 12 may be cut and the current sensor 14 connected in series using suitable electrical connectors or terminals. In other implementations, the in-line current sensor 14 may be integrated within a harness assembly or module housing configured for insertion into the vehicle lighting circuit.

In some embodiments, the current sensor 14 may comprise a resistive shunt element 56 configured to produce a voltage proportional to current flowing through the vehicle lighting conductor 12. In a preferred embodiment, the resistive shunt element 56 and associated amplification circuitry are configured to provide high-resolution measurement of very low magnitude current levels present in modern vehicle lighting conductors. Such low-level currents may be associated with LED lighting systems, standby or diagnostic currents, and multiplexed or electronically modulated vehicle lighting signals that are not reliably or consistently detectable using conventional trailer wiring interface techniques. The voltage developed across the shunt element 56 is supplied to signal conditioning circuitry 16. The signal conditioning circuitry 16 may include an amplifier 58 configured to increase the magnitude of the sensed voltage, and one or more filtering components 60 configured to attenuate unwanted high-frequency components or noise. In some embodiments, this configuration provides greater signal resolution and signal-to-noise performance than contactless sensing approaches, particularly when detecting low magnitude currents in electrically noisy vehicle environments.

The ability to accurately detect and resolve low magnitude current signals is particularly important in distinguishing between different lighting activation states in systems where multiple functions share a common conductor and where signal amplitudes may be small or dynamically varying over time. This low-current sensing capability, in combination with the temporal analysis performed by the logic and control circuitry, allows reliable interpretation of complex electrical behavior that cannot be resolved using traditional threshold-based or voltage-based detection methods.

Although FIG. 3 illustrates a resistive shunt-based in-line current sensor, it should be understood that other types of current sensing devices may be used while remaining within the scope of the present invention. For example, Hall-effect sensors, or other electrically coupled current measurement devices may be used. The in-line current sensor 14 is preferably configured to produce a measured current signal representative of current flowing in the vehicle lighting conductor 12 without materially interfering with normal operation of the vehicle lighting system.

The conditioned analog signal produced by the signal conditioning circuitry 16 is provided to the ADC 18 and to the logic and control circuitry 20 as described above.

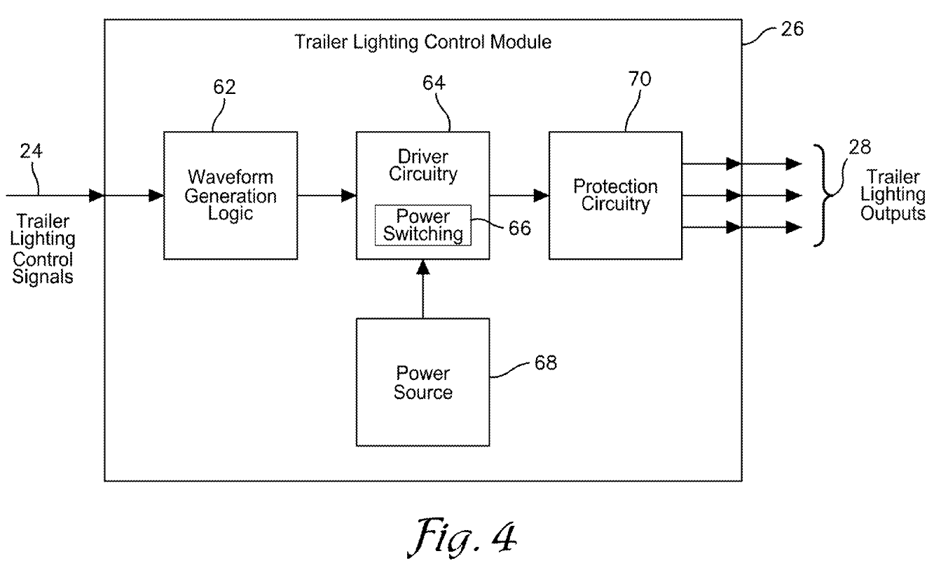

Turning now to FIG. 4, trailer lighting control module 26 is depicted in greater detail. In this embodiment, the trailer lighting control module 26 receives trailer lighting control signals 24 from the logic and control circuitry 20. The trailer lighting control module 26 includes waveform generation logic 62 configured to produce a control waveform corresponding to a determined vehicle lighting activation state. In one embodiment, for example, the waveform generation logic 62 may generate a periodic square-wave control signal for a turn signal activation state, or a sustained high-level control signal for a brake activation state.

The generated control waveform is supplied to driver circuitry 64. The driver circuitry 64 may include one or more power switching devices 66, such as field-effect transistors (FETs), bipolar transistors, solid-state relays, or electromechanical relays. The power switching devices 66 are configured to selectively connect trailer lighting outputs 28 to a power source 68, such as a vehicle’s battery, in response to the generated control waveform.

The trailer lighting control module 26 may further include protection circuitry 70 configured to protect the driver circuitry 64 and trailer lighting outputs 28 from overcurrent, short-circuit conditions, voltage transients, or thermal events. In some embodiments, the protection circuitry 70 may include current limiting components, transient voltage suppression devices, or temperature monitoring elements.

In operation, the trailer lighting control module 26 actively drives trailer lighting elements in accordance with the trailer lighting control signals 24 generated by the logic and control circuitry 20. The control waveform applied to the trailer lighting outputs 28 is based on the determined vehicle lighting activation state and may be independent of instantaneous modulation present on the vehicle lighting conductor 12. Thus, trailer lighting elements may be activated in a controlled and predictable manner corresponding to the determined activation state.

In many modern vehicle lighting architectures, a vehicle lighting conductor may carry electrical behavior corresponding to multiple lighting functions. Rather than presenting a simple steady-state on/off condition, the current flowing through the vehicle lighting conductor 12 may include non-zero baseline current, transient events, sustained current levels, and periodic variations associated with different lighting activation states. In such modern systems, direct mirroring of the measured electrical signal may not reliably produce the correct trailer lighting behavior. Instead, the measured current must be analyzed over time to determine the underlying vehicle lighting activation state.

That being the case, the following figures illustrate exemplary timing characteristics of a measured current signal and demonstrate how such signals may be processed to determine corresponding vehicle lighting activation states and to generate appropriate trailer lighting control signals.

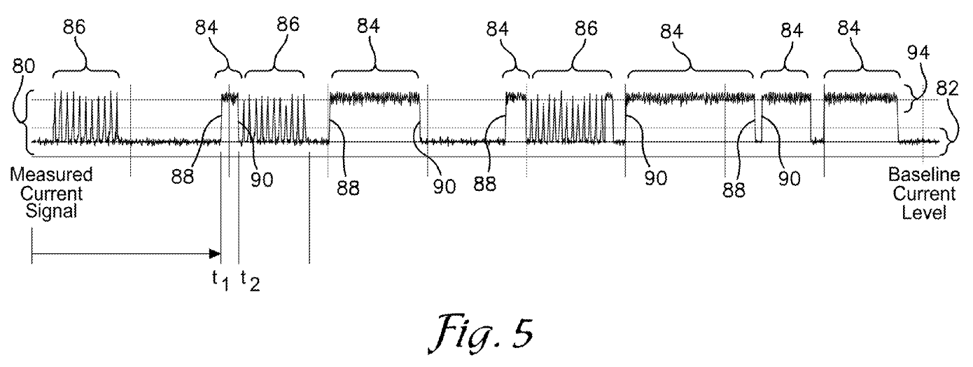

Turning to FIG. 5, a measured current signal is depicted generally as 80 as a function of time. The measured current signal 80 represents current flowing through the vehicle lighting conductor 12 as sensed by the in-line current sensor 14. As depicted in FIG. 5, the measured current signal 80 may include a non-zero baseline current level 82 present when no primary lighting function is active. The baseline current level 82 may result from background electrical behavior, standby circuitry within a vehicle lighting module, or other vehicle electrical activity.

At a first time interval, t1, the measured current signal 80 exhibits a sustained current increase 84 relative to the baseline current level 82. Such a sustained current increase 84 may correspond, for example, to activation of a running light or brake light. The sustained current increase 84 is characterized by a magnitude increase that persists for a duration exceeding a predefined time threshold.

At a second time interval,t2, the measured current signal 80 exhibits periodic current variations 86. The periodic current variations 86 may correspond to, for example, activation of a turn signal or hazard function. As illustrated in the figure, the periodic current variations 86 include a sequence of rising transitions 88 and falling transitions 90 occurring at a substantially regular repetition rate.

The measured current signal 80 may further include transient events or high-frequency modulation components 94 superimposed on the baseline or sustained current levels. Such components may be associated with pulse-width modulation (PWM), multiplexed control behavior, or other electronic switching activity within the vehicle lighting system.

As depicted in FIG. 5, the raw measured current signal 80 may comprise a combination of baseline current, sustained activation regions, periodic activation regions, and transient modulation components. Thus, reliable determination of a vehicle lighting activation state may require analysis of the measured current signal 80 over time rather than relying solely on an instantaneous current magnitude.

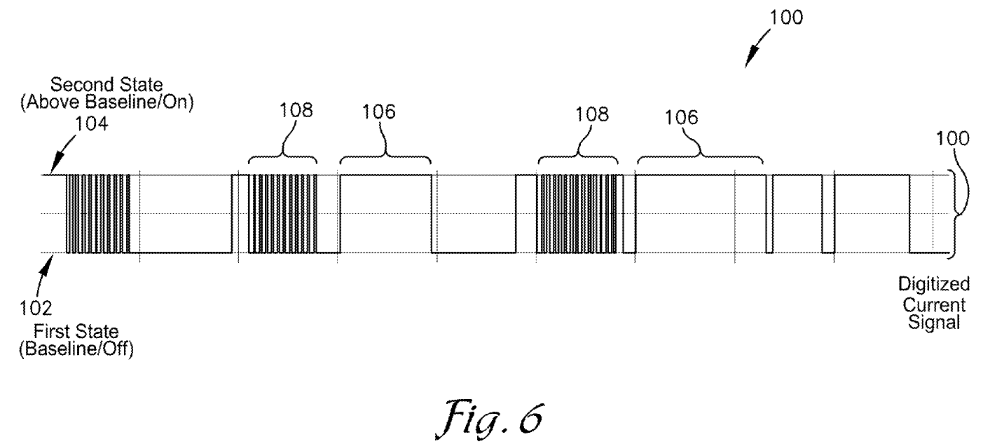

Turning now to FIG. 6, a digitized representation of a measured current signal is depicted generally as 100. The digitized current signal 100 is derived from the measured current signal 80 after conditioning by the signal conditioning circuitry 16 and conversion by the ADC 18. In one embodiment, the logic and control circuitry 20 evaluates the digitized current samples to determine whether the measured current exceeds a dynamically determined baseline level. Rather than relying solely on a fixed absolute current threshold, the logic and control circuitry 20 may determine a baseline current level based on recent historical measurements and evaluate relative changes in current with respect to the baseline.

As depicted in FIG. 6, the digitized current signal 100 includes a first state 102 corresponding to a condition in which the measured current signal 80 is at or near the baseline current level 82, and a second state 104 corresponding to a condition in which the measured current signal 80 exceeds the baseline by a predetermined margin. In one embodiment, filtering or smoothing may be applied when transitioning between the first state 102 and the second state 104 to reduce sensitivity to noise or minor fluctuations.

The digitized current signal 100 thus reflects sustained activation regions 106 corresponding to the sustained current increase 84 of FIG. 5 and periodic activation regions 108 corresponding to the periodic current variations 86 of FIG. 5. High-frequency modulation components 94 and/or transient events present in the measured current signal 80 may be filtered, averaged, or otherwise disregarded during digitization so that the digitized current signal 100 represents timing activation behavior at a lower effective frequency.

By converting the measured current signal 80 into the digitized current signal 100, the logic and control circuitry 20 obtains a simplified representation suitable for further analysis to determine a corresponding vehicle lighting activation state.

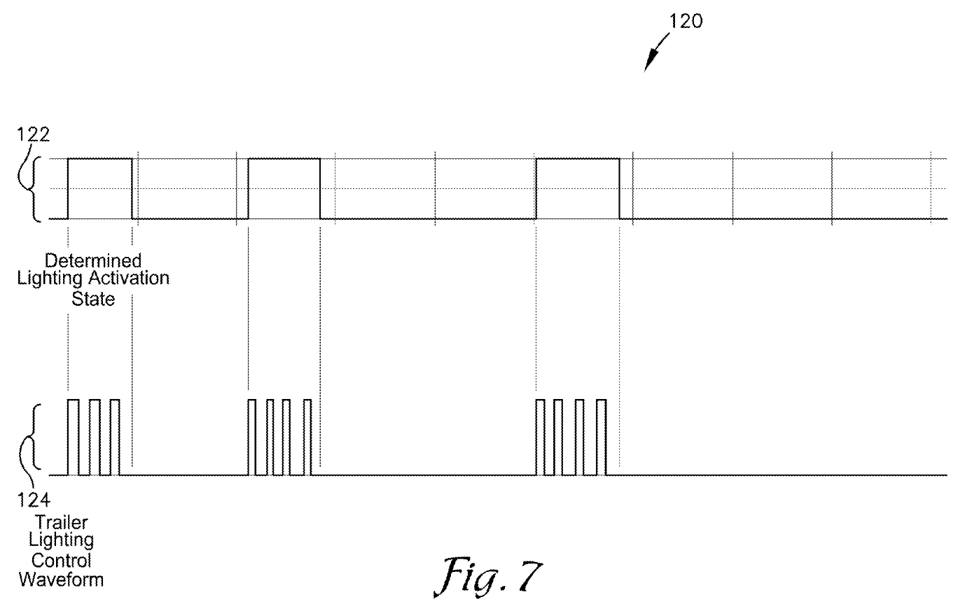

Turning now to FIG. 7, a determined lighting activation state and a corresponding generated trailer lighting control waveform are depicted generally as 120. In one embodiment, the logic and control circuitry 20 analyzes the digitized current signal 100 to identify periodic activation behavior occurring within a predefined repetition rate range. For example, periodic activation regions 108 having a repetition frequency within a range associated with turn signal operation may be classified as a turn signal activation state. The determined turn signal activation state is depicted in FIG. 7 as a state signal 122 that remains active for the duration during which periodic activation behavior is detected.

Based on the determined lighting activation state 122, the logic and control circuitry 20 generates a trailer lighting control waveform 124. In the illustrated embodiment, the trailer lighting control waveform 124 comprises a square-wave signal having a repetition rate corresponding to a desired trailer turn signal blinking pattern which may correlate with the blink rate of the vehicle turn signal, or which may be set to a desired blink rate independently of the detected blink rate. The trailer lighting control waveform 124 is supplied to the trailer lighting control module 26, which drives the trailer lighting outputs 28 according to the control waveform.

It should be understood that the trailer lighting control waveform 124 is generated based on the determined lighting activation state 122 and does not necessarily directly mirror the instantaneous modulation or transient behavior present in the measured current signal 80. For example, the high-frequency modulation components or minor fluctuations in the measured current signal 80 may be disregarded once the underlying activation state has been determined. And, in another example, while the blink rate of a turn signal provided by the trailer lighting control waveform may correspond closely to the measured blink rate from the vehicle current measurement, the blink rate of the trailer lighting control waveform is not required to correlate to the detected blink rate - i.e., the trailer lighting control waveform is a desired waveform to be generated upon detection of a state, for example, a turn signal activated on the vehicle, but the trailer lighting control signal need not necessarily correlate directly to the blink frequency, magnitude, etc. of the measured vehicle current sensor. In any case, the generated trailer lighting control waveform 124 preferably continues for approximately the same duration that the activation state 122 is determined to be active.

While FIG. 7 depicts the generation of a turn signal control waveform, it should be understood that other lighting activation states, such as brake or running light states, may result in different control waveforms or sustained output conditions applied to the trailer lighting outputs 28.

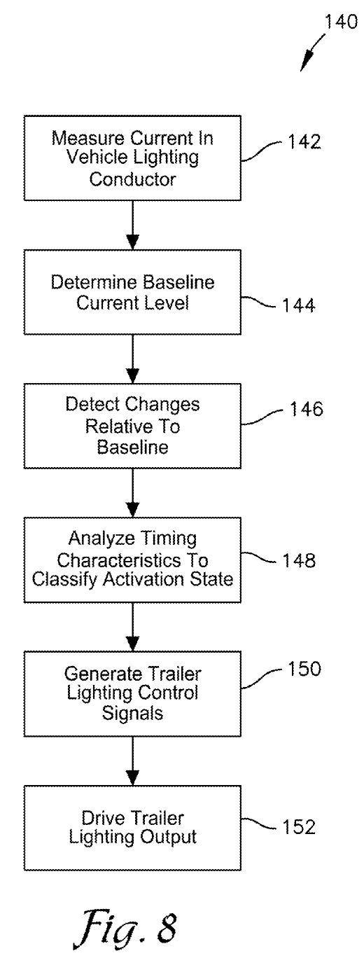

Turning to FIG. 8, an exemplary lighting state determination process is depicted generally as 140. In one embodiment, the process 140 begins at block 142 with measuring current in a vehicle lighting conductor 12 using the current sensor 14. The measured current signal is conditioned and digitized as described above.

At block 144, the logic and control circuitry 20 evaluates the digitized current signal to determine a baseline current level. The baseline may be determined based on historical samples, moving averages, or other suitable evaluation of recent signal behavior. The logic and control circuitry 20 may continuously update the baseline during operation.

At block 146, the logic and control circuitry 20 detects changes in the digitized current signal relative to the baseline. Such changes may include sustained increases in current, periodic transitions, or other temporal variations.

At block 148, the logic and control circuitry 20 analyzes timing characteristics of the detected changes to classify a vehicle lighting activation state. In one embodiment, the logic and control circuitry 20 may evaluate duration, repetition, and transition patterns to distinguish between sustained activation states and periodic activation states. The logic and control circuitry 20 may further evaluate signals from additional current sensors, when present, to corroborate or refine the classification.

At block 150, once a vehicle lighting activation state has been determined, the logic and control circuitry 20 generates one or more trailer lighting control signals 24 corresponding to the determined state. The trailer lighting control signals are supplied to the trailer lighting control module 26.

At block 152, the trailer lighting control module 26 drives the trailer lighting outputs 28 in accordance with the generated control signals.

The process as just described may preferably be performed continuously while the vehicle is in operation, allowing dynamic detection of changing lighting activation states and corresponding control of trailer lighting elements.

It should be understood that while FIG. 8 illustrates one exemplary process, the order of the steps described may vary and that additional filtering, validation, or classification steps may be included without departing from the scope of the present invention.

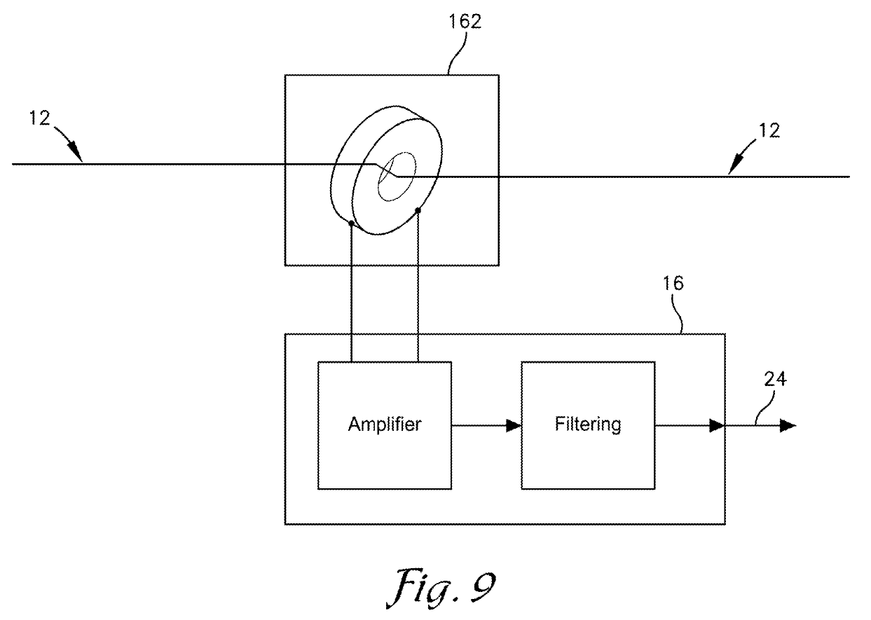

Turning now to FIG. 9, an alternative current sensing embodiment employing a contactless current sensor is depicted generally as 160. In this embodiment, the vehicle lighting conductor 12 passes through, or is positioned within, a contactless current sensor 162. The contactless current sensor 162 is configured to detect current flowing in the vehicle lighting conductor 12 without requiring direct electrical series connection. In one embodiment, the contactless current sensor 162 may comprise a magnetic field sensing device, such as a Hall-effect sensor or other non-invasive current detection element.

In contrast to conventional contactless current sensing approaches used in trailer lighting interface systems, the contactless current sensor 162 is configured to detect very low magnitude current levels and higher-frequency current variations associated with modern vehicle lighting systems, including LED-based and multiplexed lighting architectures. Conventional contactless sensing solutions are typically unable to reliably detect such low-level or high-frequency current signals and therefore cannot accurately resolve lighting activation states in these environments.

The output of the contactless current sensor 162 is supplied to the signal conditioning circuitry 16 and then to an ADC and logic and control circuitry as described above. In one embodiment, the contactless current sensor 162 and associated signal conditioning circuitry are configured with sufficient sensitivity and bandwidth to detect current levels that may be near or below the detection thresholds of conventional trailer lighting interface systems, and to capture temporal variations associated with pulse-width modulation (PWM), multiplexed control signals, or other rapidly varying electrical behavior. This enhanced sensing capability allows the logic and control circuitry to extract timing characteristics from signals that would otherwise appear as noise or remain undetectable in conventional systems. The logic and control circuitry determines vehicle lighting activation states and generates trailer lighting control signals in the same manner described with respect to the in-line current sensor embodiment.

It should be understood that a contactless current sensing embodiment may be more susceptible to environmental interference or reduced signal magnitude depending on the vehicle architecture with which the system and method of the present invention are being used. Thus, in preferred contactless embodiments, the sensing element and associated signal conditioning circuitry are selected and configured to provide sufficient sensitivity and bandwidth to resolve the low magnitude and/or high-frequency current behaviors described herein. It should be understood that the contactless embodiment is provided as an alternative configuration for measuring current in the vehicle lighting conductor 12 while still enabling determination of vehicle lighting activation states from complex modern vehicle lighting signals.

It should be further understood that the system as described herein may simultaneously measure multiple current signals from a vehicle, and analyze and determine the activation states of multiple different vehicle lighting elements (e.g., brake light, running light, turn signal light) from a single vehicle signal or from numerous vehicle signals, the configuration of which may vary depending on the vehicle in which the system is being deployed.

While specific embodiments of the present invention have been described and illustrated herein with respect to various exemplary embodiments, it should be understood that the invention is not limited to the particular structures, components, or processes shown. Instead, the various current sensing configurations, signal conditioning techniques, timing analyses, and control waveform generation methods described herein may be implemented in different forms and combinations depending on vehicle architecture and desired functionality. Modifications and variations may be made without departing from the scope of the invention as defined by the claims. Thus, the descriptions and embodiments herein are intended to be illustrative rather than limiting.

As can be seen, the systems and methods described herein are well-suited for reliable detection of lighting signals across a range of vehicle lighting architectures and configurations, including both traditional incandescent-based systems and modern digital LED-based lighting networks.

1. A system for controlling trailer lighting based on measured current in a vehicle lighting conductor, comprising:
a current sensor electrically coupled to a vehicle lighting conductor and configured to produce a measured current signal representative of current flowing through the vehicle lighting conductor;
an analog-to-digital converter configured to generate a digitized current signal from the measured current signal;
logic and control circuitry configured to analyze timing characteristics of the digitized current signal to determine a vehicle lighting activation state; and
a trailer lighting control module configured to receive a trailer lighting control signal generated by the logic and control circuitry and to control one or more trailer lighting outputs based on the determined vehicle lighting activation state.

2. The system of claim 1, wherein the current sensor comprises an in-line current sensor electrically connected in series with the vehicle lighting conductor.

3. The system of claim 2, wherein the in-line current sensor comprises a resistive shunt element and configured to allow measurement of low magnitude current variations corresponding to vehicle lighting functions.

4. The system of claim 1, wherein the logic and control circuitry is configured to determine a baseline current level and to evaluate relative changes in the digitized current signal with respect to the baseline current level.

5. The system of claim 1, wherein the logic and control circuitry is configured to identify repetitive periodic variations in the digitized current signal and to classify the periodic variations as corresponding to a turn signal activation state.

6. The system of claim 5, wherein the periodic variations occur within a predefined frequency range associated with turn signal operation.

7. The system of claim 1, wherein the logic and control circuitry is configured to identify a sustained increase in current exceeding a threshold duration and to classify the sustained increase as corresponding to a brake activation state.

8. The system of claim 1, further comprising a second current sensor electrically coupled to a second vehicle lighting conductor, wherein the logic and control circuitry is configured to combine information from the measured current signal and a second measured current signal to determine the vehicle lighting activation state.

9. The system of claim 1, wherein the logic and control circuitry is configured to generate a trailer lighting control signal corresponding to a determined turn signal activation state.

10. The system of claim 1, wherein the trailer lighting control module includes driver circuitry comprising at least one power switching device configured to selectively connect a trailer lighting output to a power source.

11. A method for controlling trailer lighting based on electrical behavior of a vehicle lighting conductor, comprising:
measuring current in a vehicle lighting conductor;
generating a digitized current signal representative of the measured current;
analyzing temporal characteristics of the digitized current signal to determine a vehicle lighting activation state; and
generating a trailer lighting control signal corresponding to the determined vehicle lighting activation state and driving one or more trailer lighting outputs based on the generated trailer lighting control signal.

12. The method of claim 11, further comprising determining a baseline current level and evaluating relative changes in the digitized current signal with respect to the baseline current level.

13. The method of claim 11, wherein analyzing temporal characteristics includes detecting periodic transitions in the digitized current signal.

14. The method of claim 13, further comprising classifying the periodic transitions as a turn signal activation state when a repetition rate falls within a predefined range.

15. The method of claim 11, further comprising identifying a sustained increase in current exceeding a threshold duration and classifying the sustained increase as a brake activation state.

16. The method of claim 11, wherein generating the trailer lighting control signal includes generating a synthesized control waveform independent of high-frequency modulation present in the measured current.

17. A trailer lighting control device configured to control trailer lighting based on electrical behavior of a vehicle lighting conductor, comprising:
an input configured to receive a measured current signal representative of current flowing in the vehicle lighting conductor;
signal conditioning circuitry and an analog-to-digital converter configured to generate a digitized current signal;
logic and control circuitry configured to analyze temporal characteristics of the digitized current signal to determine a vehicle lighting activation state; and
driver circuitry configured to generate a trailer lighting control signal and to drive one or more trailer lighting outputs based on the determined vehicle lighting activation state.

18. The trailer lighting control device of claim 17, wherein the logic and control circuitry is configured to determine a baseline current level and evaluate relative changes in the digitized current signal with respect to the baseline current level.

19. The trailer lighting control device of claim 17, wherein the logic and control circuitry is configured to identify periodic variations corresponding to a turn signal activation state and to generate a square-wave control signal for a duration corresponding to the determined activation state.

20. The trailer lighting control device of claim 17, wherein the driver circuitry includes at least one power switching device configured to selectively connect a trailer lighting output to a power source.
